(19) United States
(12) Patent Application Publication
(10) Pub. No.: US 2011/0056541 A1
(43) Pub. Date: Mar. 10, 2011

(54) Cadmium-free thin films for use in solar cells

(76) Inventors: Casiano R. Martinez, Austin, TX (US); Louay Eldada, Austin, TX (US)

(21) Appl. No.: 12/807,232

(22) Filed: Aug. 31, 2010

Related U.S. Application Data
(60) Provisional application No. 61/275,918, filed on Sep. 4, 2009.

(51) Int. Cl. H01L 31/00; H01L 31/18

(52) U.S. Cl. 136/252; 438/84; 257/E31.008

(57) ABSTRACT

A process for forming a cadmium-free thin film includes the steps of forming a first liquid precursor, forming a second liquid precursor, mixing the first and second liquid precursors in a vessel to form a coating material having no cadmium present, and dispensing the coating material from the vessel to a substrate to form the cadmium-free thin film.

### RELATED APPLICATION

The present application claims the benefit of priority from U.S. Provisional Application Ser. No. 61/275,918, filed Sep. 4, 2010.

### FIELD OF THE INVENTION

The present invention relates generally to a process for forming a cadmium-free thin film on a substrate, which can be used in the production of photovoltaic cells.

### BACKGROUND OF THE INVENTION

Solar or photovoltaic cells are devices that convert light into electricity through the photovoltaic effect. The individual photovoltaic cell is typically assembled into arrays to produce solar panels. One type of photovoltaic cell is configured in the form of a p-n diode. The p-n diode includes a thin film of a p-type material such as copper indium gallium selenide and a thin film of an n-type material or a buffer material. The most common buffer material is cadmium sulfide (CdS), which is placed in intimate contact with the thin film of the p-type material. The thin film of buffer material is typically deposited through chemical bath deposition (CBD). Although the cadmium content of the thus deposited CdS buffer layer is usually low, it is desirable to eliminate cadmium due to its toxicity in view of environmental concerns and hazards during manufacturing and handling.

In addition to eliminating cadmium, it is further desirable to develop methods of depositing buffer materials by means other than chemical bath deposition. Chemical bath deposition techniques pose significant manufacturing problems including slow growth or formation of the film, limited terminal film thickness requiring multiple runs to achieve desired thickness, use of large volume of chemicals for processing and production, non-uniformity of film thickness, and dependence on initial bath conditions (chemical concentrations, temperature, pH and the like).

Accordingly, there is a need for a process for depositing a thin film especially n-type thin films in which use of cadmium is eliminated and the deposition process is improved to address the problems associated with chemical bath deposition as mentioned above.

### SUMMARY OF THE INVENTION

The present invention relates generally to a process for forming a cadmium-free thin film on a substrate suitable for receiving the cadmium-free thin film. The cadmium-free thin film preferably includes a cadmium-free buffer material or n-type material, and the substrate is preferably a thin film of a p-type material. The process of the present invention involves mixing two or more liquid precursors of the buffer material at the point of use. The liquid precursors are allowed to react with one another under predetermined conditions to form a coating material having no cadmium present. The coating material is then dispensed onto the substrate to form the thin film of cadmium-free buffer material. In this manner, the cadmium-free thin film is formed on the substrate via chemical surface coat deposition.

In one aspect of the present invention, there is provided a process for forming a cadmium-free thin film, comprising the steps of:

a) forming a first liquid precursor;

b) forming a second liquid precursor;

c) mixing the first and second liquid precursors in a vessel to form a coating material having no cadmium present; and

d) dispensing the coating material from the vessel to a substrate to form said cadmium-free thin film.

### DETAILED DESCRIPTION OF THE INVENTION

The present invention is generally directed to a process for forming a cadmium-free thin film on a substrate. The cadmium-free thin film preferably includes a cadmium-free buffer layer or material, or n-type material, and the substrate is preferably a p-type material in the form of a thin film. The process of the present invention involves mixing two or more liquid precursors of the buffer material at the point of use. The liquid precursors each containing precursor compounds are allowed to react with one another under predetermined conditions to form a coating material having no cadmium. The coating material having no cadmium present is then dispensed onto the substrate to form the thin film of cadmium-free buffer material. In this manner, the cadmium-free thin film is formed on the substrate via chemical surface coat deposition.

The term “dispensed” as used herein means that the coating material is discharged or delivered directly onto the substrate. The process of the present invention facilitates rapid film growth, is not limited by terminal film thickness, uses smaller volumes of chemicals, provides better film thickness uniformity, eliminates at least some of the waste associated with chemical bath deposition techniques, and enhances overall quality control.

The term “n-type material” as used herein refers to a buffer material suitable for forming the n-type side (region of high electron concentration) of a p-n junction or diode found, for example, in a solar cell. Examples of such buffer materials include, but are not limited to, ZnO, Zn(O,S,OH)ₓ, ZnS, Zn(Se,OH), ZnSe, InₓSe_{y}, ZnInₓSe_{y}, Inₓ(OH,S)_{y}, In₂S₃ZnS, InS, InₓS_{y}, InₓS_{y}ZnS, and the like, wherein x and y are integers. Preferably, the buffer material is ZnS.

The term “p-type material” as used herein refers to any suitable material suitable for forming the p-type side (region of low electron concentration) of a p-n junction or diode found, for example, in a solar cell. Examples of such p-type materials include compounds of Groups IB, IIIA and VIA, including for example copper indium diselenide (CIS) and copper indium gallium diselenide (CIGS).

In a broad embodiment of the present invention, the process includes forming first and second liquid precursors of a targeted buffer material or n-type material. For example, the first precursor may include at least one salt selected from zinc salts, indium salts or a combination thereof. The second precursor may include a sulfur source and/or a selenium source.

The first and second liquid precursors will each provide one of the components of the buffer material. The first and second liquid precursors react with one another under predetermined conditions (e.g., temperature) within a reaction zone. The substrate is passed through the reaction zone in contact with the mixture of first and second liquid precursors whereby a film or coating formed from the reaction between the first and second liquid precursors is deposited on the substrate in a continuous manner. The thickness of the deposited film may be adjusted by concentration of the liquid precursors, solvent type, flow rate, temperature, and the like. It is preferred that the liquid precursors are formulated with water, and that the use of non-aqueous solvents be avoided to avert problems associated with excessive toxicity, and environmental and disposal issues.

Examples of buffer materials and corresponding precursor compounds suitable for forming cadmium-free thin films of the present invention are provided below in Table 1.

TABLE 1

| Buffer | |
|---|---|
| Materials | Precursor Compounds |
| ZnO | zinc salt (e.g., zinc sulfate (ZnSO₄)) + ammonium hydroxide |
| | (NH₄OH) |
| ZnS | zinc salt (e.g., zinc sulfate (ZnSO₄)) + ammonium hydroxide |
| | (NH₄OH) + sulfur source (e.g., thiourea: SC(NH₂)₂) |
| ZnSe | zinc salt (e.g., zinc sulfate (ZnSO₄)) + ammonium hydroxide |
| | (NH₄OH) + selenium source (e.g., selenourea: |
| | NH₂CSeNH₂) |
| InₓSe_{y} | indium salt (e.g., indium chloride (InCl₃)) + ammonium |
| | hydroxide (NH₄OH) + selenium source (e.g., selenourea: |
| | NH₂CSeNH₂) |
| ZnInₓSe_{y} | zinc salt (e.g., zinc sulfate (ZnSO₄)) + indium salt (e.g., |
| | indium chloride (InCl₃)) + ammonium hydroxide (NH₄OH) + |
| | selenium source (e.g., selenourea: NH₂CSeNH₂) |
| InₓS_{y} | indium salt (e.g., indium chloride (InCl₃)) + sulfur source |
| | (e.g., thioacetamide: C₂H₅NS) + acid (e.g., hydrochloric acid |
| | (HCl), acetic acid (CH₃COOH)) |
| InₓS_{y}ZnS | indium salt (e.g., indium chloride (InCl₃)) + zinc salt (e.g., |
| | zinc sulfate (ZnSO₄)) + ammonium hydroxide (NH₄OH) + |
| | sulfur source (e.g., thiourea: SC(NH₂)₂, thioacetamide: |
| | C₂H₅NS) + acid (e.g., hydrochloric acid (HCl), acetic acid |
| | (CH₃COOH)) |

In one embodiment of the present invention, the process includes forming first and second liquid precursors of a targeted buffer material or n-type material such as zinc sulfide (ZnS). The first and second liquid precursors will each provide one of the components of the buffer material. Thus, in the formation of ZnS, the first precursor will typically be a zinc salt and the second precursor a composition such that the first and second precursors can react under the predetermined conditions and in the presence of other materials which will facilitate the formation of ZnS. It is preferred that the liquid precursors are formulated with water, and that the use of non-aqueous solvents be avoided to avert problems associated with excessive toxicity, and environmental and disposal issues.

For the production of a zinc sulfide buffer material, a first liquid precursor may be composed of a solution of zinc sulfate (ZnSO₄), preferably at a concentration of about 0.1M, and ammonium hydroxide (NH₄OH), preferably at a concentration of about 1.5M. The second liquid precursor may be composed of a solution of thiourea (SC(NH₂)₂), preferably at a concentration of about 0.4M, and ammonium hydroxide, preferably at a concentration of about 1.5M. The first and second liquid precursors are mixed together and the resulting mixture is heated to a reaction temperature for a time sufficient to induce a reaction between the first and second precursors to yield a cadmium-free coating material. The reaction temperature may be about 60° C. to 90° C., and preferably from about 65° to 85°, and more preferably at about 75° C., and the reaction time may be about 60 seconds.

The coating material having no cadmium present is dispensed through any suitable coating techniques where the coating material is discharged or delivered onto a substrate as opposed to chemical bath deposition in which the substrate is immersed in a bath of coating material. Such suitable coating techniques include, but not limited to, extrusion die coating, curtain coating, bead coating, roll coating, gap coating, slide coating, knife coating, air knife coating, jet coating, spray coating, drip coating, and the like.

The substrate may be composed of a glass support coated with an electrode material such as molybdenum with a thin film of a p-type material overlaying the electrode material.

The p-type material is selected, for example, from copper indium selenide (CIS), and CIS formed by the addition of gallium, sulfur, or aluminum, and/or combinations thereof. Preferably, the p-type material is copper indium gallium selenide (CIGS). It will be understood that the substrate is not limited to these compositions, and may include any p-type material such as those disclosed in U.S. Pat. No. 6,500,733, the entire content of which is incorporated herein by reference.

The substrate is preferably moved into a deposition chamber during the dispensing of the coating material thereon. In this manner, the conditions of the process can be actively controlled. The coating material, substrate and the deposition chamber may be maintained at a reaction temperature suitable for forming the coated substrate. The reaction temperature is preferably from about 60° C. to 90° C., more preferably from about 65° to 85° C., and most preferably about 80° C. Optionally, the substrate is heated prior to passage through the deposition chamber. The substrate is preferably heated to a temperature of from about 50° C. to 90° C., and more preferably from about 70° to 80° C. The temperature of the coating material, substrate and chamber is preferably maintained within a relatively narrow range, most preferably within a range of no more than about 2° C. The coating material may be dispensed onto the substrate in an amount suitable to produce the desired thin film such as about 60 ml per square foot of the substrate surface area.

The coating material facilitates the formation of a cadmium-free thin film onto the surface of the substrate at the dispensing temperature. The substrate with the cadmium-free thin film is then rinsed with a solvent, preferably an aqueous solvent such as de-ionized (DI) water, dried with compressed air, and annealed in air at an annealing temperature of about 200° C. for a time of about 10 minutes.

### Example

A procedure for forming a thin film of a buffer material of zinc sulfide (ZnS) on a glass substrate with a thin film of copper indium gallium selenide (CIGS) on a thin film of molybdenum thereon is described below.

Two chemical solutions are prepared: Precursor A includes of 0.1M zinc sulfate (ZnSO₄) mixed with 1.5M ammonium hydroxide (NH₄OH) and precursor B includes of 0.4M thiourea (SC(NH₂)₂) mixed with 1.5M ammonium hydroxide (NH₄OH). At a slot-die coating tool, the two precursors are pumped separately into a mixer, and the resulting mixed solution is subsequently pumped into a heat exchanger for a period of about 60 seconds in order to reach a reaction temperature of 75° C. The residence time in the heat exchanger also brings the chemical reaction to a state of linear growth upon contact.

A glass substrate with a thin film of copper indium gallium selenide (CIGS) on a thin film of molybdenum enters a deposition chamber, where the substrate and chamber are held at a constant temperature of 80° C. The temperature of the chamber and the substrate and the temperature of the mixed solution are actively controlled to ensure a constant temperature uniformity within 2° C. (This is in contrast to the 5° C. temperature uniformity typically observed in conventional chemical bath deposition (CBD) processes.) The solution flows subsequently through the slot die of the coating tool as the substrate moves on a conveyor under the die to receive approximately 60 ml of the solution per square foot of substrate area.

The products of the reaction between precursor A and precursor B in the solution precipitate on the surface of the substrate and thereby form a thin film of zinc sulfide (ZnS). A ZnS film thickness of approximately 40 nm is achieved by passing the substrate under the slot die twice at a conveyor speed of 1.6 in/sec and a dwell time of 5 minutes after each pass. The substrate is subsequently rinsed with de-ionized (DI) water, dried with compressed air, and annealed in air at 200° C. for 10 minutes.

The foregoing discussion discloses and describes merely exemplary embodiments of the present invention. One skilled in the art will readily recognize from such discussion, and from the accompanying drawings and claims, that various changes, modifications and variations can be made therein without departing from the spirit and scope of the invention as defined in the following claims.

What is claimed is:

1. A process for forming a cadmium-free thin film, comprising the steps of:
a) forming a first liquid precursor;
b) forming a second liquid precursor;
c) mixing the first and second liquid precursors in a vessel to form a coating material having no cadmium present; and
d) dispensing the coating material from the vessel to a substrate to form said cadmium-free thin film.

2. The process of claim 1 wherein the first liquid precursor comprises at least one salt selected from zinc salts and indium salts.

3. The process of claim 1 wherein the second liquid precursor comprises at least one source selected from a sulfur source and a selenium source.

4. The process of claims 1 further comprising conducting the dispensing step at a reaction temperature for a sufficient time to enable the first and second liquid precursors to react with each other.

5. The process of claim 4 wherein the reaction temperature is from about 60° C. to 90° C.

6. The process of claim 5 wherein the reaction temperature is from about 65° C. to 85° C.

7. The process of claim 6 wherein the reaction temperature is about 75° C.

8. The process of claim 1 wherein the cadmium-free thin film comprises a buffer material.

9. The process of claim 8 wherein the buffer material is an n-type material.

10. The process of claim 9 wherein the n-type material is selected from the group consisting of ZnO, Zn(O,S,OH)ₓ, ZnS, Zn(Se,OH), ZnSe, InₓSe_{y}, ZnInₓSe_{y}, Inₓ(OH,S)_{y}, In₂S₃ZnS, InS, InₓS_{y}, and InₓS_{y}ZnS, wherein x and y are integers.

11. The process of claim 1 further comprising maintaining a temperature uniformity within a range of no more than about 2° C. between the coating solution and the substrate during the dispensing step.

12. The process of claim 1 wherein the buffer material is ZnS.

13. The process of claim 12 wherein the first liquid precursor comprises a solution of zinc sulfate and ammonium hydroxide.

14. The process of claim 12 wherein the second liquid precursor comprises a solution of thiourea and ammonium hydroxide.

15. The process of claim 1 wherein the substrate comprises a thin film of a p-type material.

16. The process of claim 15 wherein the p-type material is selected from the group consisting of copper indium gallium selenide and copper indium selenide.

17. The process of claim 15 wherein the substrate further comprises a thin film of an electrode material.

18. The process of claim 17 wherein the electrode material is comprised of molybdenum.

19. A solar cell comprising a p-type material, a cadmium-free n-type material and an electrode.
